(19) United States
(12) Patent Application Publication
(10) Pub. No.: US 2024/0396567 A1
(43) Pub. Date: Nov. 28, 2024

(54) DIGITAL CORRECTION METHOD FOR DYNAMIC RANGE EXPANSION OF MULTIPLE ADCS

(71) Applicant: University of Electronic Science and Technology of China, Chengdu (CN)

(72) Inventors: Hao Li, Chengdu (CN); Jiawei Cao, Chengdu (CN); Yangbin Wei, Chengdu (CN); Xuyang Li, Chengdu (CN); Guangkun Luo, Chengdu (CN)

(21) Appl. No.: 18/635,047

(22) Filed: Apr. 15, 2024

(30) Foreign Application Priority Data
May 22, 2023 (CN) 2023105777203

(51) Int. Cl. H03M 1/10; H03M 1/16; H03M 1/18

(52) U.S. Cl. CPC H03M 1/1023; H03M 1/167; H03M 1/18

(57) ABSTRACT

A digital correction method for dynamic range expansion of multiple ADCs includes: obtaining gain and offset correction values of other channels relative to a standard channel CH₁ based on iterative computations through positive and negative amplitude auxiliary values and positive and negative base values, then performing gain-offset error correction on the other channels, and then calculating phase differences of the other channels relative to the standard channel CH₁ and constructing fractional delay filters with a Farrow structure corresponding to the channels, correcting sampling data X₂, . . . , X_{M} after performing the gain-offset error correction. Digital correction of sampling data collected from multiple channels in a multi-ADC system is realized while ensuring that respective dynamic ranges of the sampling data with different gains output by the multiple channels are not lost.

### TECHNICAL FIELD

The disclosure relates to the field of dynamic signal analysis (DSA), particularly to a digital correction method for dynamic range expansion of multiple analog-to-digital converters (ADCs).

### BACKGROUND

A maximum range and a minimum measurable signal of an instrument determine performance of dynamic testing, and the minimum measurable signal of the instrument is determined by noise suppression performance of an analog device corresponding to a channel and a resolution of an analog-to-digital converter (ADC). Throughout a development process of indices in a dynamic range (DR) of a dynamic signal analyzer, improvements of the ADC resolution and a process of the analog device can lead to a significant increase in the DR. However, with the increasing resolution of ADC nowadays, the improvement in the process of the analog device becomes slower and more difficult. When using a single ADC to collect signals under a condition that a noise of the channel is ideal, a DR of a system depends on an index of a signal-to-noise ratio of the ADC, and signals beyond a measurement range of the single ADC cannot be tested by the system. Therefore, using multiple ADCs to complete data acquisition can break through the DR limitation corresponding to the single ADC.

A key to an expansion technology of the multiple ADCs is how to integrate sampling data collected from multiple channels into one channel. However, the expansion technology faces two major challenges: 1) how to correct gains and offsets of the sampling data collected from the multiple channels to unify the multiple ADCs at the same quantization accuracy; and 2) how to correct different time delays between the sampling data collected from the multiple channels.

### SUMMARY

An objective of the disclosure is to overcome deficiencies in the related art, thereby providing a digital correction method for dynamic range expansion of multiple analog-to-digital converters (ADCs), which can complete digital correction of sampling data collected from multiple channels in a multi-ADC system while ensuring that respective dynamic ranges of the sampling data with different gains output by the multiple channels are not lost, so as to integrate the sampling data collected from the multiple ADCs into a data stream in a single channel.

In order to achieve the above objective, the digital correction method for dynamic range expansion of multiple ADCs is provided by the disclosure, a number of channels of the multiple ADCs is M; and the digital correction method includes the following steps:
step 1, obtaining a gain correction value Aₘ, 1≤m≤M−1 and an offset correction value Bₘ, 1≤m≤M−1 of each channel in target channels of the M channels by iterative computations, and performing gain-offset error correction on each of the target channels based on the gain correction value Aₘ and the offset correction value Bₘ;
the M channels having different gains and different offset errors, and the M channels being denoted as CH₁, CH₂, CH₃, . . . , CH_{M}; sampling data of the M channels CH₁, CH₂, CH₃, . . . , CH_{M} being respectively denoted as X₁, X₂, . . . , X_{M}; the channel CH₁ of the M channels being determined as a reference channel, and the gain-offset error correction being performed on the channels CH₂, CH₃, . . . , CH_{M}, as the target channels, of the M channels according to gain correction values A₁, A₂, . . . , A_{M-1} of the channels CH₂, CH₃, . . . , CH_{M} relative to the channel CH₁ and offset correction values B₁, B₂, . . . , B_{M-1} of the channels CH₂, CH₃, . . . , CH_{M} relative to the channel CH₁ by the following formula:

$$\{ \begin{matrix}{X}_{2} = {A}_{1} {X}_{2} + {β}_{1} \\ {X}_{3} = {A}_{2} {X}_{3} + {β}_{2} \\ … \\ {X}_{M} = {A}_{M - 1} {X}_{M} + {B}_{M - 1}\end{matrix}$$

the gain correction values A₁, A₂, . . . , Aₘ₋₁ of the channels CH₂, CH₃, . . . , CH_{M} relative to the channel CH₁ and the offset correction values B₁, B₂, . . . , Bₘ₋₁ of the channels CH₂, CH₃, . . . , CH_{M} relative to the channel CH₁ being obtained by performing the iterative computations on bipolar signals of the sampling data of two channels of the M channels; and the obtaining the gain correction value Aₘ and the offset correction value Bₘ including the following steps:
   step 1.1, selecting a first sampling data segment with a length L from the sampling data of the channel CH₁ and a second sampling data segment with the length L from the sampling data of the channel CHₘ₊₁, denoting the first sampling data segment corresponding to the channel CH₁ as X₁(0), X₁(1), . . . , X₁(L−1) and denoting the second sampling data segment corresponding to the channel CHₘ₊₁ as Xₘ₊₁(0), Xₘ₊₁(1), . . . , Xₘ₊₁(L−1); initializing a number of the iterative computations i=1, initializing a positive amplitude auxiliary value P(0)=X₁(0), initializing a negative amplitude auxiliary value N(0)=X₁(0), initializing the gain correction value Aₘ(0)=1, and initializing the offset correction value Bₘ(0)=0;
   step 1.2, calculating a positive amplitude auxiliary value P(i) of an i^{th} iterative computation and a negative amplitude auxiliary value N(i) of the i^{th} iterative computation according to the following formula:

$$P ( i ) = P ( i - 1 ) +$$

$$[ {X}_{1} ( i - 1 ) + ( {X}_{PMax} - {X}_{m + 1} ( i - 1 ) ) \times {A}_{m} ( i - 1 ) + {B}_{m} ( i - 1 ) - P ( i - 1 ) ] \times {D}^{′}$$

$$N ( i ) = N ( i - 1 ) +$$

$$[ {X}_{1} ( i - 1 ) + ( {X}_{NMax} - {X}_{m + 1} ( i - 1 ) ) \times {A}_{m} ( i - 1 ) + {B}_{m} ( i - 1 ) - N ( i - 1 ) ] \times {D}^{′}$$

where X_{PMax} represents a positive base value and is determined as a positive maximum value of a higher gain channel between the channel CH₁ and the channel CHₘ₊₁; X_{NMax} represents a negative base value and is determined as a negative maximum value of the higher gain channel between the channel CH₁ and the channel CHₘ₊₁; Aₘ(i−1) represents a gain correction value of an (i−1)^{th} iterative computation; Bₘ(i−1) represents an offset correction value of the (i−1)^{th} iterative computation; and D′ represents an iteration speed;
step 1.3, calculating a gain correction value Aₘ(i) of the i^{th} iterative computation and an offset correction value Bₘ(i) of the i^{th} iterative computation according to the following formula:

$${A}_{m} ( i ) = \frac{P ( i ) - N ( i )}{{X}_{PMax} - {X}_{NMax}} \\ {B}_{m} ( i ) = \frac{{X}_{PMax} \times N ( i ) - {X}_{NMax} \times P ( i )}{2 \times ( {X}_{PMax} - {X}_{NMax} )}$$

step 1.4, calculating an error Δₘ(i) of the i^{th} iterative computation according to the following formula:

$${Δ}_{m} ( i ) = {X}_{1} ( i ) - [ {A}_{m} ( i ) \times {X}_{m + 1} ( i ) + {B}_{m} ( i ) ]$$

step 1.5, determining whether the error Δₘ(i) is less than a set iteration precision; when the error Δₘ(i) is less than the set iteration precision, determining the gain correction value Aₘ(i) of the i^{th} iterative computation and the offset correction value Bₘ(i) of the i^{th} iterative computation as the gain correction value Aₘ and the offset correction value Bₘ; or when the error Δₘ(i) is equal to or greater than the set iteration precision, determining i=i+1 and returning and performing the step 1.2;
step 2, obtaining delays of the M channels, constructing a fractional delay filter with a Farrow structure, and performing delay correction on the M channels, which includes the following steps:
   step 2.1, obtaining the delays of the target channels, including:
      inputting standard signals with same frequency and same phase into the M channels CH₁, CH₂, CH₃, . . . , CH_{M}; performing fast Fourier transform (FFT) on the sampling data of the M channels CH₁, CH₂, CH₃, . . . , CH_{M} to obtain results corresponding to the M channels CH₁, CH₂, CH₃, . . . , CH_{M}; and obtaining phases φₘ, m=1, 2, . . . , M of the M channels CH₁, CH₂, CH₃, . . . , CH_{M} according to real parts REₘ and imaginary parts IMₘ, m=1, 2, . . . , M of the results by using the following formula:

$${φ}_{m} = arc tan ( \frac{{IM}_{m}}{{RE}_{m}} )$$

obtaining phase differences Δφ₁, Δφ₂, . . . , Δφ_{M-1} of the channels CH₂, CH₃, . . . , CH_{M} relative to the channel CH₁ by the following formula:

$${Δφ}_{m} = {φ}_{m + 1} - {φ}_{1} , m = 1 , 2 , … , M - 1$$

obtaining the delays τₘ, m=1, 2, . . . , M−1 of the channels CH₂, CH₃, . . . , CH_{M} relative to the channel CH₁ by the following formula:

$${τ}_{m} = \frac{{k}^{′}}{360 ° {f}_{0}} {Δφ}_{m}$$

where f₀ represents a frequency of each of the standard signals, and k′ represents a sampling rate of each of the multiple ADCs;
step 2.2, designing the fractional delay filter with the Farrow structure, including:
   determining a coefficient of a fractional delay filter base on Lagrange interpolation by obtaining a maximum flatness in a passband of the fractional delay filter based on Lagrange interpolation; and the coefficient of the fractional delay filter based on Lagrange interpolation being expressed as follows:

$$h ( n ) = {\prod }_{\begin{matrix}k = 0 \\ k \neq n\end{matrix}}^{P} \frac{D - k}{n - k} , n = 0 , 1 , 2 , … , P$$

where P represents an order of the fractional delay filter based on Lagrange interpolation, D=P−2+d, and d represents a fractional delay within a range of 0≤d≤1;
using a wave filter with a Farrow structure to approximate the determined coefficient h(n) of the fractional delay filter based on Lagrange interpolation, thereby obtaining the fractional delay filter with the Farrow structure within the fractional delay of 0≤d≤1 by using the wave filter with the Farrow structure, and obtaining a polynomial h′(n) for the coefficient h(n) of the fractional delay filter based on Lagrange interpolation according to D=P−2+d, and the polynomial h′(n) for the coefficient h(n) of the fractional delay filter based on Lagrange interpolation being expressed by the following formula:

$${h}^{′} ( n ) = {\sum }_{P = 0}^{P} {c}_{P} ( n ) {d}^{P} , n = 0 , 1 , 2 , … , P$$

where c_{P}(n) represents a coefficient of the fractional delay filter with the Farrow structure;
for the channels CH₂, CH₃, . . . , CH_{M}, the delays Σₘ, m=1, 2, . . . , M−1 being determined as d respectively, and a polynomial hₘ(n) for the coefficient of the fractional delay filter with the Farrow structure corresponding to the channels CH₂, CH₃, . . . , CH_{M} respectively being obtained as follows:

$${h}_{m} ( n ) = {\sum }_{P = 0}^{P} {c}_{P} ( n ) {τ}_{m}^{P} , n = 0 , 1 , 2 , … , P , m = 1 , 2 , … , M - 1$$

for the channel CH₁, a decimal delay τ₀ being a constant and being determined as d, and a polynomial h₀(n) for the coefficient of the fractional delay filter with the Farrow structure corresponding to the channel CH₁ being obtained as follows:

$${h}_{0} ( n ) = {\sum }_{P = 0}^{P} {c}_{P} ( n ) {τ}_{0}^{P} , n = 0 , 1 , 2 , … , P$$

step 2.3, performing the delay correction on the M channels, including:
   performing half-band interpolation on the sampling data X₁ corresponding to the channel CH₁ and the sampling data X₂, . . . , X_{M} corresponding to the channels CH₂, CH₃, . . . , CH_{M} after the gain-offset error correction performed in the step 1 to obtain processed sampling data, and inputting the processed sampling data into the fractional delay filters h₀(n), h₁(n), . . . , h_{M-1}(n) with the Farrow structure corresponding to the M channels CHI₁ CH₂, CH₃, . . . , CH_{M} respectively to perform delay filtering, and then performing half-band extraction after the delay filtering to obtain delay-corrected sampling data X₁, X₂, . . . , X_{M}, thereby completing the delay correction on the M channels; and
step 3, data integration, including:
   integrating the delay-corrected sampling data X₁, X₂, . . . , X_{M} to obtain a multi-ADC acquisition signal.

Specially, the decimal delay τ₀ is set with a precision of ten thousandth of a sampling point.

The objective of the disclosure is realized as follows. The disclosure provides the digital correction method for dynamic range expansion of multiple ADCs, which uses the positive amplitude auxiliary value and the negative amplitude auxiliary value, the positive base value and the negative base value to perform the iterative computations to obtain the gain correction values and the offset correction values of the channels relative to the channel CHI₁, thereby performing the gain-offset error correction on the channels except for the channel CH₁. Then, the phase differences of the channels relative to the standard channel CH₁ are calculated to construct the fractional delay filters with the Farrow structure, and the sampling data X₂, . . . , X_{M} performed by the gain-offset error correction are further corrected. The disclosure ensures that the respective dynamic ranges of the sampling data with different gains output by the multiple channels are not lost, while completing the digital correction of the sampling data collected from the multiple channels in the multi-ADC system.

### BRIEF DESCRIPTION OF DRAWINGS

FIG. 1 illustrates a schematic diagram of a flowchart of a digital correction method for dynamic range expansion of multiple ADCs according to an embodiment of the disclosure.

FIG. 2 illustrates a flowchart of obtaining a gain correction value Aₘ and an offset correction value Bₘ in step 1 illustrated in FIG. 1.

FIG. 3 illustrates a schematic diagram of a principle of the digital correction method for dynamic range expansion of multiple ADCs according to the embodiment of the disclosure.

FIG. 4 illustrates a schematic diagram of obtaining a phase difference.

FIG. 5A illustrates a schematic diagram of an output signal before digital correction.

FIG. 5B illustrates a schematic diagram of the output signal after the digital correction.

### DETAILED DESCRIPTION OF EMBODIMENTS

Embodiments of the disclosure are described below with reference to attached drawings, so that those skilled in the related art can better understand the disclosure. It should be noted that in the following description, these detailed descriptions will be omitted here when the detailed descriptions of the known functions and designs may fade the main content of the disclosure.

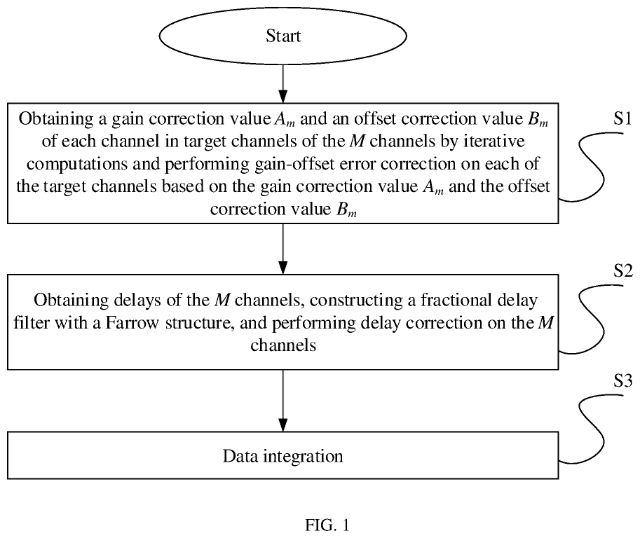

FIG. 1 illustrates a schematic diagram of a flowchart of a digital correction method for dynamic range expansion of multiple analog-to-digital converters (ADCs) according to an embodiment of the disclosure.

In the embodiment, as shown in FIG. 1, a number of channels of the multiple ADCs is M; and the digital correction method for dynamic range expansion of multiple ADCs according to the disclosure includes the following steps.

Step 1, a gain correction value Aₘ, 1≤m≤M−1 and an offset correction value Bₘ, 1≤m≤M−1 of each channel in target channels of the M channels are obtained by iterative computations, and gain-offset error correction is performed on each of the target channels based on the gain correction value Aₘ and the offset correction value Bₘ.

The M channels have different gains and different offset errors, and the M channels are denoted as CH₁, CH₂, CH₃, . . . , CH_{M}; sampling data of the M channels CH₁, CH₂, CH₃, . . . , CH_{M} are respectively denoted as X₁, X₂, . . . , X_{M}; and the channel CH₁ of the M channels is determined as a reference channel. In the embodiment, a channel with a minimum gain of the M channels is determined as the channel CH₁, which avoids a loss of dynamic range during digital correction process.

The gain-offset error correction is performed on the channels CH₂, CH₃, . . . , CH_{M}, as the target channels, of the M channels according to gain correction values A₁, A₂, . . . , A_{M-1} of the channels CH₂, CH₃, . . . , CH_{M} relative to the channel CH₁ and offset correction values B₁, B₂, . . . , B_{M-1} of the channels CH₂, CH₃, . . . , CH_{M} relative to the channel CH₁ by the following formula:

$$\{ \begin{matrix}{X}_{2} = {A}_{1} {X}_{2} + {B}_{1} \\ {X}_{3} = {A}_{2} {X}_{3} + {B}_{2} \\ … \\ {X}_{M} = {A}_{M - 1} {X}_{M} + {B}_{M - 1}\end{matrix} .$$

In an embodiment, the gain correction values A₁, A₂, . . . , A_{M-1} of the channels CH₂, CH₃, . . . , CH_{M} relative to the channel CH₁ and the offset correction values B₁, B₂, . . . , B_{M-1} of the channels CH₂, CH₃, . . . , CH_{M} relative to the channel CH₁ are obtained by performing the iterative computations on bipolar signals of the sampling data of two channels (i.e., a to-be-corrected channel selected from the channels CH₂, CH₃, . . . , CH_{M} and the reference channel CH₁) of the M channels. Since the bipolar signals are divided into positive amplitude and negative amplitude, the iterative computations introduce several additional auxiliary values, including: using a positive maximum value of a higher gain channel between the to-be-corrected channel and the reference channel CH₁ as a positive base value X_{PMax}, using a negative maximum value of the higher gain channel between the to-be-corrected channel and the reference channel CH₁ as a negative base value X_{NMax}, a positive amplitude auxiliary value P(i), and a negative amplitude auxiliary value N(i). P(i) and N(i) are used for calculating the gain correction values A₁, A₂, . . . , A_{M-1} and the offset correction values B₁, B₂, . . . , B_{M-1} during the iteration computations.

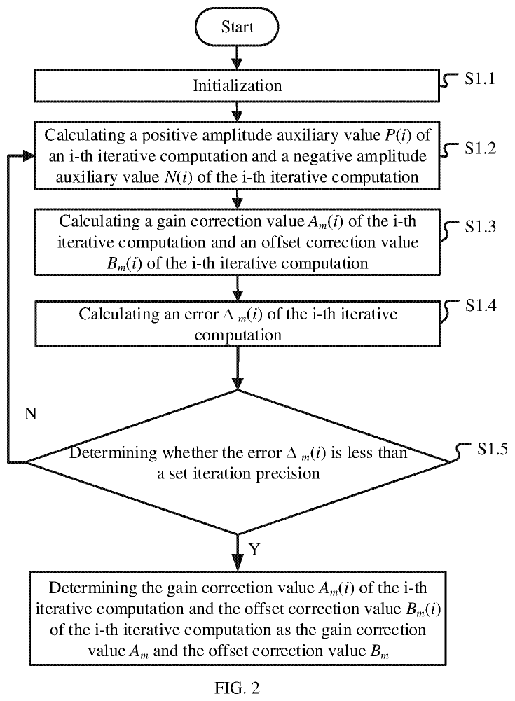

Specifically, as shown in FIG. 2, the obtaining the gain correction value Aₘ and the offset correction value Bₘ includes the following steps.

Step 1.1, an initialization is performed.

A sampling data segment (also referred to a first sampling data segment) with a length L is selected from the sampling data of the channel CH₁ and a sampling data segment (also referred to a second sampling data segment) with the length L is selected from the sampling data of the channel CHₘ₊₁, the sampling data segment corresponding to the channel CH₁ is denoted as X₁(0), X₁(1), . . . , X₁(L−1) and the sampling data segment corresponding to the channel CHₘ₊₁ is denoted as Xₘ₊₁(0), Xₘ₊₁(1), . . . , Xₘ₊₁(L−1); a number of the iterative computations is initialized by i=1, a positive amplitude auxiliary value is initialized by P(0)=X₁(0), a negative amplitude auxiliary value is initialized by N(0)=X₁(0), the gain correction value is initialized by Aₘ(0)=1, and the offset correction value is initialized by Bₘ(0)=0.

Step 1.2, a positive amplitude auxiliary value P(i) of an i^{th} iterative computation and a negative amplitude auxiliary value N(i) of the i^{th} iterative computation are calculated according to the following formula:

$$P ( i ) = P ( i - 1 ) +$$

$$[ {X}_{1} ( i - 1 ) + ( {X}_{PMax} - {X}_{m + 1} ( i - 1 ) ) \times {A}_{m} ( i - 1 ) + {B}_{m} ( i - 1 ) - P ( i - 1 ) ] \times {D}^{′} ;$$

$$N ( i ) = N ( i - 1 ) +$$

$$[ {X}_{1} ( i - 1 ) + ( {X}_{NMax} - {X}_{m + 1} ( i - 1 ) ) \times {A}_{m} ( i - 1 ) + {B}_{m} ( i - 1 ) - N ( i - 1 ) ] \times {D}^{′} .$$

In the above formula, X_{PMax} represents a positive base value and is determined as a positive maximum value of a higher gain channel between the channel CH₁ and the channel CHₘ₊₁; X_{NMax} represents a negative base value and is determined as a negative maximum value of the higher gain channel between the channel CH₁ and the channel CHₘ₊₁; Aₘ(i−1) represents a gain correction value of an (i−1)^{th} iterative computation; Bₘ(i−1) represents an offset correction value of the (i−1)^{th} iterative computation; and D′ represents an iteration speed.

Step 1.3, a gain correction value Aₘ(i) of the i^{th} iterative computation and an offset correction value Bₘ(i) of the i^{th} iterative computation are calculated according to the following formula:

$${A}_{m} ( i ) = \frac{P ( i ) - N ( i )}{{X}_{PMax} - {X}_{NMax}} ; \\ {B}_{m} ( i ) = \frac{{X}_{PMax} \times N ( i ) - {X}_{NMax} \times P ( i )}{2 \times ( {X}_{PMax} - {X}_{NMax} )} .$$

Step 1.4, an error Δₘ(i) of the i^{th} iterative computation is calculated according to the following formula:

$${Δ}_{m} ( i ) = {X}_{1} ( i ) - [ {A}_{m} ( i ) \times {X}_{m + 1} ( i ) + {B}_{m} ( i ) ] .$$

Step 1.5, whether the error Δₘ(i) is less than a set iteration precision is determined; when the error Δₘ(i) is less than the set iteration precision, the gain correction value Aₘ(i) of the i^{th} iterative computation and the offset correction value Bₘ(i) of the i^{th} iterative computation are determined as the gain correction value Aₘ and the offset correction value Bₘ; or when the error Δₘ(i) is equal to or greater than the set iteration precision, i=i+1 is determined and step 1.2 is returned and performed.

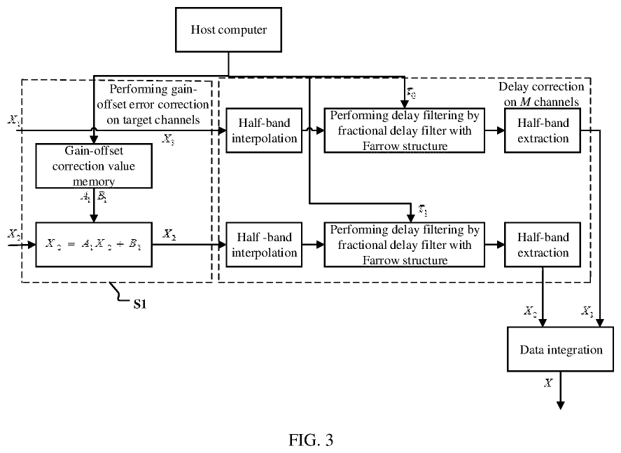

Since the multiple ADCs are similar, in an illustrated embodiment, as shown in FIG. 3, two ADCs are used as an example for description. In the embodiment, the disclosure only needs to calculate the gain correction value A₁ and the offset correction value B₁ of the channel CH₂, and to perform the gain-offset error correction on the channel CH₂ according to a formula as follows:

$${X}_{2} = {A}_{1} {X}_{2} + {B}_{1} .$$

Step 2: delays of the M channels are obtained, a fractional delay filter with a Farrow structure is constructed (the multiple M channels corresponding to multiple fractional delay filters with the Farrow structure), and delay correction is performed on the M channels.

In an embodiment, the step 2 includes the following steps.

Step 2.1: the delays of the target channels are obtained.

In the step 2.1, in combination with spectrum analysis, a corresponding phase spectrum is obtained according to a corresponding real part and a corresponding imaginary part based on fast Fourier transform (FFT), which is convenient for measuring a phase difference of a signal at a certain frequency point. When measuring the delay of a single frequency point, the standard signal corresponding to the single frequency point is input through a signal source, the standard signals with same frequency and same phase are input into the M channels, the channel CH₁ is used as the reference channel, phases of M standard frequency points corresponding to the M channels are calculated based on FFT, and then phase differences of the channels CH₂, CH₃, . . . , CH_{M} relative to the channel CH₁ at the same frequency point are obtained, thereby estimating the delay of the to-be-corrected channel relative to the channel CH₁ according to the corresponding phase difference of the single frequency point.

Specifically, the step of obtaining the delays of the target channels includes the following steps:
inputting standard signals with same frequency and same phase into the M channels CH₁, CH₂, CH₃, . . . , CH_{M}; performing fast Fourier transform (FFT) on the sampling data of the M channels CH₁, CH₂, CH₃, . . . , CH_{M} to obtain results corresponding to the M channels CH₁, CH₂, CH₃, . . . , CH_{M}; and obtaining phases φₘ, m=1, 2, . . . , M of the M channels CH₁, CH₂, CH₃, . . . , CH_{M} according to real parts REₘ and imaginary parts IMₘ, m=1, 2, . . . , M of the results by using the following formula:

$${φ}_{m} = arc tan ( \frac{{IM}_{m}}{{RE}_{m}} ) ;$$

obtaining phase differences Δφ₁, Δφ₂, . . . , Δφ_{M-1} of the channels CH₂, CH₃, . . . , CH_{M} relative to the channel CH₁ by the following formula:

$${Δφ}_{m} = {φ}_{m + 1} - {φ}_{1} , m = 1 , 2 , … , M - 1 ;$$

obtaining the delays τₘ, m=1, 2, . . . , M−1 of the channels CH₂, CH₃, . . . , CH_{M} relative to the channel CH₁ by the following formula:

$${τ}_{m} = \frac{{k}^{′}}{360 ° {f}_{0}} {Δφ}_{m} ;$$

where f₀ represents a frequency of each of the standard signals, and k′ represents a sampling rate of each of the multiple ADCs.

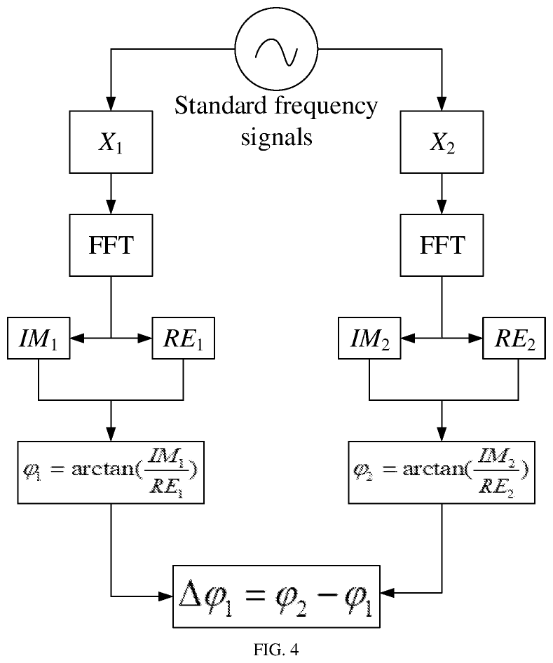

In an illustrated embodiment, the sampling rate of the ADC is 262.144 kilohertz (kHz), and an analysis bandwidth of the multi-ADS system is 102.4 kHz. As shown in FIG. 4, a host computer obtains the phase difference corresponding to the certain frequency point according to the real parts RE₁ and RE₂ and the imaginary part IM₁ and IM₂ based on the FFT. When the delay of the single frequency point is measured, the standard signal with a frequency of 1.024 kHz is input into each channel of the M channels through the signal source, the sampling rate is 262.144 kHz, and an FFT analysis at 8192 points is performed, so that the standard signal with the frequency of 1.024 kHz is located at a point of the 32^{th} FFT, and then the corresponding imaginary part and the corresponding real part are IM₁ and IM₂ and RE₁ and RE₂, the phase difference Δφ₁ between the phase φ₁ and the phase φ₂ is obtained by Δφ₁=φ₂−φ₁; and the phase φ₁ and the phase φ₂ are calculated by arctangent values between the real parts of RE₁ RE₂ and the imaginary parts of IM₁ IM₂ of the two channels (i.e., the channel CH₁ and the channel CH₂) based on the FFT. If the phase difference Δφ₁ between the two channels at the same frequency point is 0.08°, and the delay τ₁ between the two channels is estimated according to the phase difference of the single frequency point as follows:

$${τ}_{1} = \frac{{k}^{′}}{360 ° {f}_{0}} {Δφ}_{1} = \frac{262.144 kHz \times 0.08 °}{1.024 kHz \times 360 °} = 0.05689 .$$

Step 2.2: the fractional delay filter with the Farrow structure is designed, including the following steps:
determining a coefficient of a fractional delay filter base on Lagrange interpolation by obtaining a maximum flatness in a passband of the fractional delay filter based on Lagrange interpolation; and the coefficient of the fractional delay filter based on Lagrange interpolation being expressed as follows:

$$h ( n ) = {\prod }_{\begin{matrix}k = 0 \\ k \neq n\end{matrix}}^{P} \frac{D - k}{n - k} , n = 0 , 1 , 2 , … , P$$

where P represents an order of the fractional delay filter based on Lagrange interpolation, D=P−2+d, and d represents a fractional delay within a range of 0 d≤1.

In an illustrated embodiment, the order P of the fractional delay filter based on Lagrange interpolation is P=3, which is taken as an example, the coefficient of the fractional delay filter based on Lagrange interpolation is shown in Table 1 as follows:

TABLE 1

| h(0) | h(1) | h(2) | h(3) |
|---|---|---|---|
| P = 3 -(D-1)(D-2)(D-3)/6 | D(D-2)(D-3)/2 | -D(D-1)(D-3)/2 | D(D-1)(D-2)/6 |

The step 2.2 further includes: using a wave filter with a Farrow structure to approximate the determined coefficient h(n) of the fractional delay filter based on Lagrange interpolation, thereby obtaining an optimal fractional delay filter (i.e., the fractional delay filter with the Farrow structure) within the fractional delay of 0≤d≤1 by using the wave filter with the Farrow structure, and obtaining a polynomial h′(n) for the coefficient h(n) of the fractional delay filter based on Lagrange interpolation according to D=P−2+d, and the polynomial h′(n) for the coefficient h(n) of the fractional delay filter based on Lagrange interpolation being expressed by the following formula:
h′(n)=Σ_{P=0}^{P}c_{P}(n)d^{P}, n=0, 1, 2, . . . , P, where c_{P}(n) represents a coefficient of the fractional delay filter with the Farrow structure.

In an illustrated embodiment, the order P of the fractional delay filter based on Lagrange interpolation is P=3, an expression of the coefficient of the fractional delay filter based on Lagrange interpolation with third-order Farrow structure is expressed as follows:

$$\{ \begin{matrix}{h}_{d} ( 0 ) = - \frac{1}{6} {d}^{3} + \frac{1}{2} {d}^{2} - \frac{1}{3} d \\ {h}_{d} ( 1 ) = \frac{1}{2} {d}^{3} - {d}^{2} - \frac{1}{2} d + 1 \\ {h}_{d} ( 2 ) = - \frac{1}{2} {d}^{3} + \frac{1}{2} {d}^{2} + d \\ {h}_{d} ( 3 ) = \frac{1}{6} {d}^{3} - \frac{1}{6} d\end{matrix} .$$

The coefficient c_{P}(n) of the fractional delay filter with the third-order Farrow structure according to the Lagrange interpolation is obtained as follows:

$${c}_{p} ( n ) = ( \begin{matrix}{c}_{3} ( 0 ) & {c}_{2} ( 0 ) & {c}_{1} ( 0 ) & {c}_{0} ( 0 ) \\ {c}_{3} ( 1 ) & {c}_{2} ( 1 ) & {c}_{1} ( 1 ) & {c}_{0} ( 1 ) \\ {c}_{3} ( 2 ) & {c}_{2} ( 2 ) & {c}_{1} ( 2 ) & {c}_{0} ( 2 ) \\ {c}_{3} ( 3 ) & {c}_{2} ( 3 ) & {c}_{1} ( 3 ) & {c}_{0} ( 3 )\end{matrix} ) = ( \begin{matrix}- \frac{1}{6} & \frac{1}{2} & - \frac{1}{3} & 0 \\ \frac{1}{2} & - 1 & - \frac{1}{2} & 1 \\ - \frac{1}{2} & \frac{1}{2} & 1 & 0 \\ \frac{1}{6} & 0 & - \frac{1}{6} & 0\end{matrix} ) .$$

For the channels CH₂, CH₃, . . . , CH_{M}, the delays τₘ, m=1, 2, . . . , M−1 obtained in the step 2.1 are determined as d respectively, and therefore the fractional delay filters hₘ(n) with the Farrow structure (also referred to the polynomials for the coefficient of the fractional delay filter with the Farrow structure) corresponding to the channels CH₂, CH₃, . . . , CH_{M} are obtained as follows:

$${h}_{m} ( n ) = {\sum }_{P = 0}^{P} {c}_{P} ( n ) {τ}_{m}^{P} , n = 0 , 1 , 2 , … , P , m = 1 , 2 , … , M - 1$$

For the channel CH₁, a decimal delay τ₀ with a precision of ten thousandth of a sampling point is determined as d, and the polynomial h₀(n) for the coefficient of the fractional delay filter with the Farrow structure corresponding to the channel CH₁ is obtained as follows:

$${h}_{0} ( n ) = {\sum }_{P = 0}^{P} {c}_{P} ( n ) {τ}_{0}^{P} , n = 0 , 1 , 2 , … , P$$

Specially, the decimal delay τ₀ is a constant.

Step 2.3: the delay correction is performed on the M channels as follows.

The delay correction uses the fractional delay filters with the Farrow structure corresponding to the M channels to eliminate delay inconsistency of the sampling data of the M channels. Meanwhile, due to the fact that a bandwidth of the fractional delay filter with the Farrow structure is designed to be low by using the maximum flatness in the passband of the fractional delay filter based on Lagrange interpolation, the interpolation can be used to improve data rate, and data extraction can be performed after the delay correction is realized by the fractional delay filter with the Farrow structure. Specifically, the step 2.3 includes the following steps: performing half-band interpolation on the sampling data X₁ corresponding to the channel CH₁ and the sampling data X₂, . . . , X_{M} corresponding to the channels CH₂, CH₃, . . . , CH_{M} after the gain-offset error correction performed in the step 1 to obtain processed sampling data, and inputting the processed sampling data into the fractional delay filters (also referred to the polynomials for the coefficient of the fractional delay filter with the Farrow structure corresponding to the M channels obtained in the step 2.2) h₀(n), h₁(n), . . . , h_{M-1}(n) with the Farrow structure corresponding to the M channels CH₁, CH₂, CH₃, . . . , CH_{M} respectively to perform delay filtering, and then performing half-band extraction after the delay filtering to obtain delay-corrected sampling data X₁, X₂, . . . , X_{M}, thereby completing the delay correction on the M channels.

In an illustrated embodiment, as shown in FIG. 3, the sampling data X₁ corresponding to the channel CH₁ and the sampling data X₂ corresponding to the channel CH₂ after the gain-offset error correction is performed in the step 1 are respectively subjected to the half-band interpolation, and then respectively sent to the corresponding fractional delay filter with the Farrow structure respectively, i.e., h₀(n) and h₁(n), to perform the delay filtering, and then the half-band extraction is performed after the delay filtering to obtain delay-corrected sampling data X₁ and X₂, thereby completing the delay correction on the channel CH₁ and the channel CH₂.

In an illustrated embodiment, the disclosure use a seven-order wave filter with the Farrow structure to perform channel fixed delay correction based on linear phase characteristic, a normalized passband of the seven-order wave filter with the Farrow structure is only 52 kHz at the sampling rate of 262.144 kHz, the sampling rate is first increased to 524.288 kHz by using the half-band interpolation, and at this time, the passband of the seven-order wave filter with the Farrow structure meets a passband requirement of 105 kHz.

The sampling data of the two channels are corrected by the seven-order wave filter with the Farrow structure respectively. Specially, the fractional delay filter with the Farrow structure is set with a small delay of 0.0001 (i.e., the constant for the decimal delay) to compensate for the amplitude and full cycle delay of the sampling data in the channel CH₁.

Step 3: data integration is performed.

The step 3 includes: integrating the delay-corrected sampling data X₁, X₂, . . . , X_{M} to obtain a multi-ADC acquisition signal.

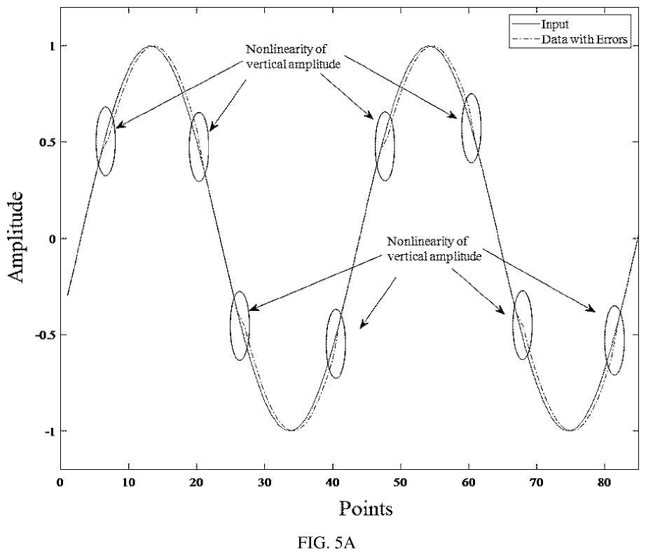

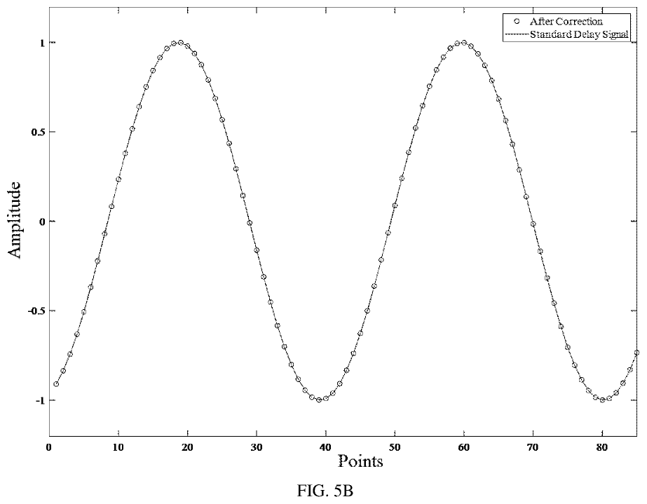

According to an actual application scenario of dynamic range expansion, sampling data with different amplitudes needs to be selected for integration by more different gains of the multiple channels. In an illustrated embodiment, the input signal is a sine wave, as shown in FIG. 5A, circles illustrated in FIG. 5A indicate occurrence points of vertical nonlinearity caused by delay error after data integration, and it can be seen that due to the existence of the delay error, time domain waveform of an output signal generates obvious distortion. Meanwhile, as shown in FIG. 5B, after the digital correction is performed, the two lines illustrated in FIG. 5B coincide with each other to represent the correction filter to well correct the delay error, so that the waveform distortion is improved.

Although the foregoing has been described with respect to the illustrated embodiments of the disclosure, it will be apparent to those skilled in the related art that the disclosure is not limited to the scope of the illustrated embodiments. Moreover, it will be apparent to those skilled in the related art that such variations are obvious to those skilled in the related art, as long as the variations fall within the spirit and scope of the disclosure, all of which are protected by the disclosure.

What is claimed is:

1. A digital correction method for dynamic range expansion of multiple analog-to-digital converters (ADCs), wherein a number of channels of the multiple ADCs is M; and the digital correction method comprises the following steps:
step 1, obtaining a gain correction value Aₘ, 1≤m≤M−1 and an offset correction value Bₘ, 1≤m≤M−1 of each channel in target channels of the M channels by iterative computations, and performing gain-offset error correction on each of the target channels based on the gain correction value Aₘ and the offset correction value Bₘ;
wherein the M channels have different gains and different offset errors, and the M channels are denoted as CH₁, CH₂, CH₃, . . . , CH_{M}; sampling data of the M channels CH₁, CH₂, CH₃, . . . , CH_{M} are respectively denoted as X₁, X₂, . . . , X_{M}; the channel CH₁ of the M channels is determined as a reference channel, and the gain-offset error correction is performed on the channels CH₂, CH₃, . . . , CH_{M}, as the target channels, of the M channels according to gain correction values A₁, A₂, . . . , A_{M-1} of the channels CH₂, CH₃, . . . , CH_{M} relative to the channel CH₁ and offset correction values B₁, B₂, . . . , B_{M-1} of the channels CH₂, CH₃, . . . , CH_{M} relative to the channel CH₁ by the following formula:
$$\{ \begin{matrix}{X}_{2} = {A}_{1} {X}_{2} + {B}_{1} \\ {X}_{3} = {A}_{2} {X}_{3} + {B}_{2} \\ … \\ {X}_{M} = {A}_{M - 1} {X}_{M} + {B}_{M - 1}\end{matrix} ;$$
wherein the gain correction values A₁, A₂, . . . , A_{M-1} of the channels CH₂, CH₃, . . . , CH_{M} relative to the channel CH₁ and the offset correction values B₁, B₂, . . . , B_{M-1} of the channels CH₂, CH₃, . . . , CH_{M} relative to the channel CH₁ are obtained by performing the iterative computations on bipolar signals of the sampling data of two channels of the M channels; and the obtaining the gain correction value Aₘ and the offset correction value Bₘ comprises the following steps:
step 1.1, selecting a first sampling data segment with a length L from the sampling data of the channel CH₁ and a second sampling data segment with the length L from the sampling data of the channel CHₘ₊₁, denoting the first sampling data segment corresponding to the channel CH₁ as X₁(0), X₁(1), . . . , X₁(L−1) and denoting the second sampling data segment corresponding to the channel CHₘ₊₁ as Xₘ₊₁(0), Xₘ₊₁(1), . . . , Xₘ₊₁(L−1); initializing a number of the iterative computations i=1, initializing a positive amplitude auxiliary value P(0)=X₁(0), initializing a negative amplitude auxiliary value N(0)=X₁(0), initializing the gain correction value Aₘ(0)=1, and initializing the offset correction value Bₘ(0)=0;
step 1.2, calculating a positive amplitude auxiliary value P(i) of an i^{th} iterative computation and a negative amplitude auxiliary value N(i) of the i^{th} iterative computation according to the following formula:
$$P ( i ) = P ( i - 1 ) +$$
$$[ {X}_{1} ( i - 1 ) + ( {X}_{PMax} - {X}_{m + 1} ( i - 1 ) ) \times {A}_{m} ( i - 1 ) + {B}_{m} ( i - 1 ) - P ( i - 1 ) ] \times {D}^{′} ;$$
$$N ( i ) = N ( i - 1 ) +$$
$$[ {X}_{1} ( i - 1 ) + ( {X}_{NMax} - {X}_{m + 1} ( i - 1 ) ) \times {A}_{m} ( i - 1 ) + {B}_{m} ( i - 1 ) - N ( i - 1 ) ] \times {D}^{′} ;$$
wherein X_{PMax} represents a positive base value and is determined as a positive maximum value of a higher gain channel between the channel CH₁ and the channel CHₘ₊₁; X_{NMax} represents a negative base value and is determined as a negative maximum value of the higher gain channel between the channel CH₁ and the channel CHₘ₊₁; Aₘ(i−1) represents a gain correction value of an (i−1)^{th} iterative computation; Bₘ(i−1) represents an offset correction value of the (i−1)^{th} iterative computation; and D′ represents an iteration speed;
step 1.3, calculating a gain correction value Aₘ(i) of the i^{th} iterative computation and an offset correction value Bₘ(i) of the i^{th} iterative computation according to the following formula:
$${A}_{m} ( i ) = \frac{P ( i ) - N ( i )}{{X}_{PMax} - {X}_{NMax}} ; \\ {B}_{m} ( i ) = \frac{{X}_{PMax} \times N ( i ) - {X}_{NMax} \times P ( i )}{2 \times ( {X}_{PMax} - {X}_{NMax} )} ;$$
step 1.4, calculating an error Δₘ(i) of the i^{th} iterative computation according to the following formula:
$${Δ}_{m} ( i ) = {X}_{1} ( i ) - [ {A}_{m} ( i ) \times {X}_{m + 1} ( i ) + {B}_{m} ( i ) ] ;$$
step 1.5, determining whether the error Δₘ(i) is less than a set iteration precision; when the error Δₘ(i) is less than the set iteration precision, determining the gain correction value Aₘ(i) of the i^{th} iterative computation and the offset correction value Bₘ(i) of the i^{th} iterative computation as the gain correction value Aₘ and the offset correction value Bₘ; or when the error Δₘ(i) is equal to or greater than the set iteration precision, determining i=i+1 and returning and performing the step 1.2;
step 2, obtaining delays of the M channels, constructing a fractional delay filter with a Farrow structure, and performing delay correction on the M channels;
wherein the step 2 comprises the following steps:
step 2.1, obtaining the delays of the target channels, comprising:
inputting standard signals with same frequency and same phase into the M channels CH₁, CH₂, CH₃, . . . , CH_{M}; performing fast Fourier transform (FFT) on the sampling data of the M channels CH₁, CH₂, CH₃, . . . , CH_{M} to obtain results corresponding to the M channels CH₁, CH₂, CH₃, . . . , CH_{M}; and obtaining phases φₘ, m=1, 2, . . . , M of the M channels CH₁, CH₂, CH₃, . . . , CH_{M} according to real parts REₘ and imaginary parts IMₘ, m=1, 2, . . . , M of the results by using the following formula:
$${φ}_{m} = arc tan ( \frac{{IM}_{m}}{{RE}_{m}} ) , m = 1 , 2 , … , M ;$$
obtaining phase differences Δφ₁, Δφ₂, . . . , Δφ_{M-1} of the channels CH₂, CH₃, . . . , CH_{M} relative to the channel CH₁ by the following formula:
$${Δφ}_{m} = {φ}_{m + 1} - {φ}_{1} , m = 1 , 2 , … , M - 1 ;$$
obtaining the delays τₘ, m=1, 2, . . . , M−1 of the channels CH₂, CH₃, . . . , CH_{M} relative to the channel CH₁ by the following formula:
$${τ}_{m} = \frac{{k}^{′}}{360 ° {f}_{0}} {Δφ}_{m} ;$$
where f₀ represents a frequency of each of the standard signals, and k′ represents a sampling rate of each of the multiple ADCs;
step 2.2, designing the fractional delay filter with the Farrow structure, comprising:
determining a coefficient of a fractional delay filter base on Lagrange interpolation by obtaining a maximum flatness in a passband of the fractional delay filter based on Lagrange interpolation; and the coefficient of the fractional delay filter based on Lagrange interpolation being expressed as follows:
$$h ( n ) = {\prod }_{\begin{matrix}k = 0 \\ k \neq n\end{matrix}}^{P} \frac{D - k}{n - k} , n = 0 , 1 , 2 , … , P ;$$
wherein P represents an order of the fractional delay filter based on Lagrange interpolation, D=P−2+d, and d represents a fractional delay within a range of 0≤d≤1;
using a wave filter with a Farrow structure to approximate the determined coefficient h(n) of the fractional delay filter based on Lagrange interpolation, thereby obtaining the fractional delay filter with the Farrow structure within the fractional delay of 0≤d≤1 by using the wave filter with the Farrow structure, and obtaining a polynomial h′(n) for the coefficient h(n) of the fractional delay filter based on Lagrange interpolation according to D=P−2+d, and the polynomial h′(n) for the coefficient h(n) of the fractional delay filter based on Lagrange interpolation being expressed by the following formula:
$${h}^{′} ( n ) = {\sum }_{P = 0}^{P} {c}_{P} ( n ) {d}^{P} , n = 0 , 1 , 2 , … , P ;$$
wherein c_{P}(n) represents a coefficient of the fractional delay filter with the Farrow structure;
wherein for the channels CH₂, CH₃, . . . , CH_{M}, the delays τₘ, m=1, 2, . . . , M−1 are determined as d respectively, and a polynomial for the coefficient of the fractional delay filter with the Farrow structure corresponding to the channels CH₂, CH₃, . . . , CH_{M} respectively is obtained as follows:
$${h}_{m} ( n ) = {\sum }_{P = 0}^{P} {c}_{P} ( n ) {τ}_{m}^{P} , n = 0 , 1 , 2 , … , P , m = 1 , 2 , … , M - 1 ;$$
wherein for the channel CH₁, a decimal delay τ₀ is a constant and is determined as d, and a polynomial for the coefficient of the fractional delay filter with the Farrow structure corresponding to the channel CH₁ is obtained as follows:
$${h}_{0} ( n ) = {\sum }_{P = 0}^{P} {c}_{P} ( n ) {τ}_{0}^{P} , n = 0 , 1 , 2 , … , P ;$$
step 2.3, performing the delay correction on the M channels, comprising:
performing half-band interpolation on the sampling data X₁ corresponding to the channel CH₁ and the sampling data X₂, . . . , X_{M} corresponding to the channels CH₂, CH₃, . . . , CH_{M} after the gain-offset error correction performed in the step 1 to obtain processed sampling data, and inputting the processed sampling data into the fractional delay filters h₀(n), h₁(n), . . . , h_{M-1}(n) with the Farrow structure corresponding to the M channels CH₁, CH₂, CH₃, . . . , CH_{M} respectively to perform delay filtering, and then performing half-band extraction after the delay filtering to obtain delay-corrected sampling data X₁, X₂, . . . , X_{M}, thereby completing the delay correction on the M channels; and
step 3, data integration, comprising:
integrating the delay-corrected sampling data X₁, X₂, . . . , X_{M} to obtain a multi-ADC acquisition signal.

2. The digital correction method for dynamic range expansion of multiple ADCs according to claim 1, further comprising: determining a channel with a minimum gain of the M channels as the channel CH₁.
